(19) United States
(12) Patent Application Publication
(10) Pub. No.: US 2016/0065275 A1
(43) Pub. Date: Mar. 3, 2016

(54) MULTIPLE INPUT MULTIPLE OUTPUT COMMUNICATIONS OVER NONLINEAR CHANNELS USING ORTHOGONAL FREQUENCY DIVISION MULTIPLEXING

(71) Applicant: MagnaCom Ltd., Petach Tikva (IL)

(72) Inventors: Ilan Reuven, Ganey Tikva (IL); Amir Eliaz, Moshav Ben Shemen (IL); Shimon Benjo, Petach Tikva (IL); Daniel Stopler, Holon (IL); Roy Oren, Magshimim (IL)

(21) Appl. No.: 14/836,366

(22) Filed: Aug. 26, 2015

Related U.S. Application Data
(60) Provisional application No. 62/042,286, filed on Aug. 27, 2014.
(60) Provisional application No. 62/049,428, filed on Sep. 12, 2014.
(60) Provisional application No. 62/047,721, filed on Sep. 9, 2014.

(51) Int. Cl. H04B 7/04; H03M 13/00; H03M 13/11

(52) U.S. Cl. CPC H04B 7/0413; H03M 13/1111; H03M 13/611

(57) ABSTRACT

An OFDM receiver comprises a (FEC) decoder and a nonlinearity compensation circuit. The nonlinearity compensation circuit is operable to generate estimates of constellation points transmitted on each of a plurality of subcarriers of a received signal based on soft decisions from the FEC decoder and based on a model of nonlinear distortion introduced by a transmitter from which the received signal was received. The generation of the estimates may be based on a measure of distance between a function of the received signal and a synthesized version of the received signal. The generation of the estimates may comprise iterative processing of symbols of the received signal, and the iterative processing may comprise a plurality of outer iterations and a plurality of inner iterations.

### CLAIM OF PRIORITY

### Priority Claim

This application claims priority to the following application(s), each of which is hereby incorporated herein by reference:
U.S. provisional patent application 62/042,286 titled “Multiple Input Multiple Output Communications Over Nonlinear Channels Using Orthogonal Frequency Division Multiplexing” filed on Aug. 27, 2014;
U.S. provisional patent application 62/049,428 titled “Multiple Input Multiple Output Communications Over Nonlinear Channels Using Orthogonal Frequency Division Multiplexing” filed on Sep. 12, 2014; and
U.S. provisional patent application 62/047,721 titled “Multiple Input Multiple Output Communications Over Nonlinear Channels Using Orthogonal Frequency Division Multiplexing” filed on Sep. 9, 2014.

### INCORPORATION BY REFERENCE

This application claims priority to the following application(s), each of which is hereby incorporated herein by reference:
U.S. patent application Ser. No. 14/809,408 titled “Orthogonal Frequency Division Multiplexing Based Communications over Nonlinear Channels” filed on Jul. 27, 2015.

### BACKGROUND

Limitations and disadvantages of conventional and traditional methods and systems for electronic communications will become apparent to one of skill in the art, through comparison of such systems with some aspects of the present invention as set forth in the remainder of the present application with reference to the drawings.

### BRIEF SUMMARY OF THE INVENTION

A system and/or method is provided for multiple input multiple output communications over nonlinear channels, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF THE FIGURES

FIG. 1 depicts a transmitter in accordance with an example implementation of this disclosure.

FIG. 2 depicts AM-to-AM and AM-to-PM response of a typical power amplifier with and without intervention by the digital predistortion circuit of the transmitter.

FIG. 3 depicts a receiver in accordance with an example implementation of this disclosure.

### DETAILED DESCRIPTION

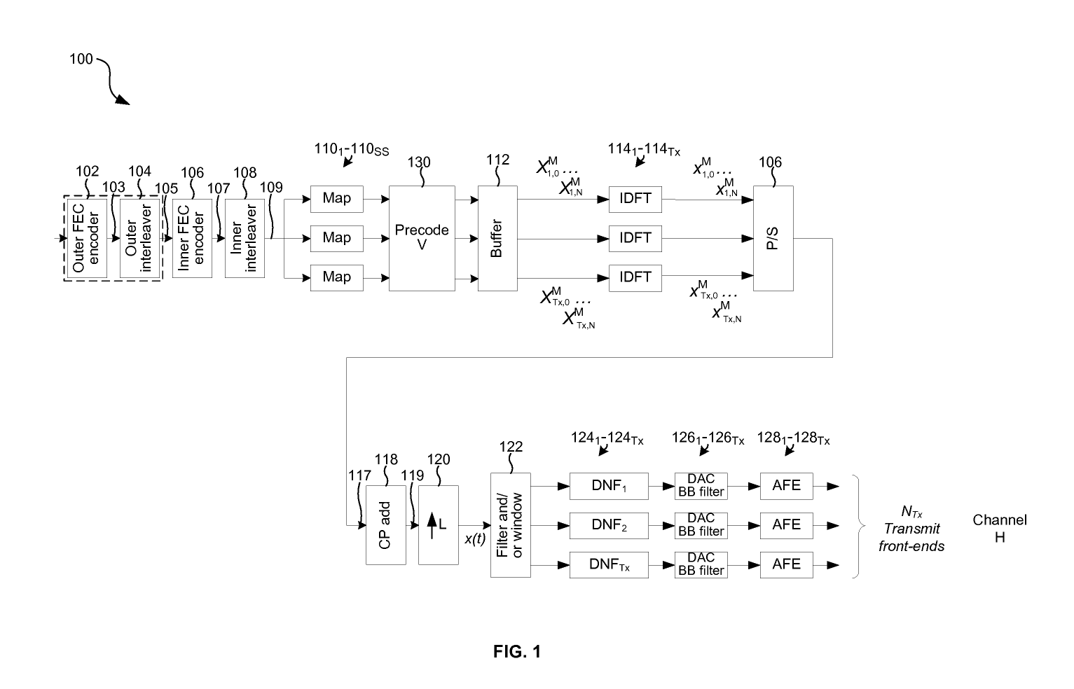

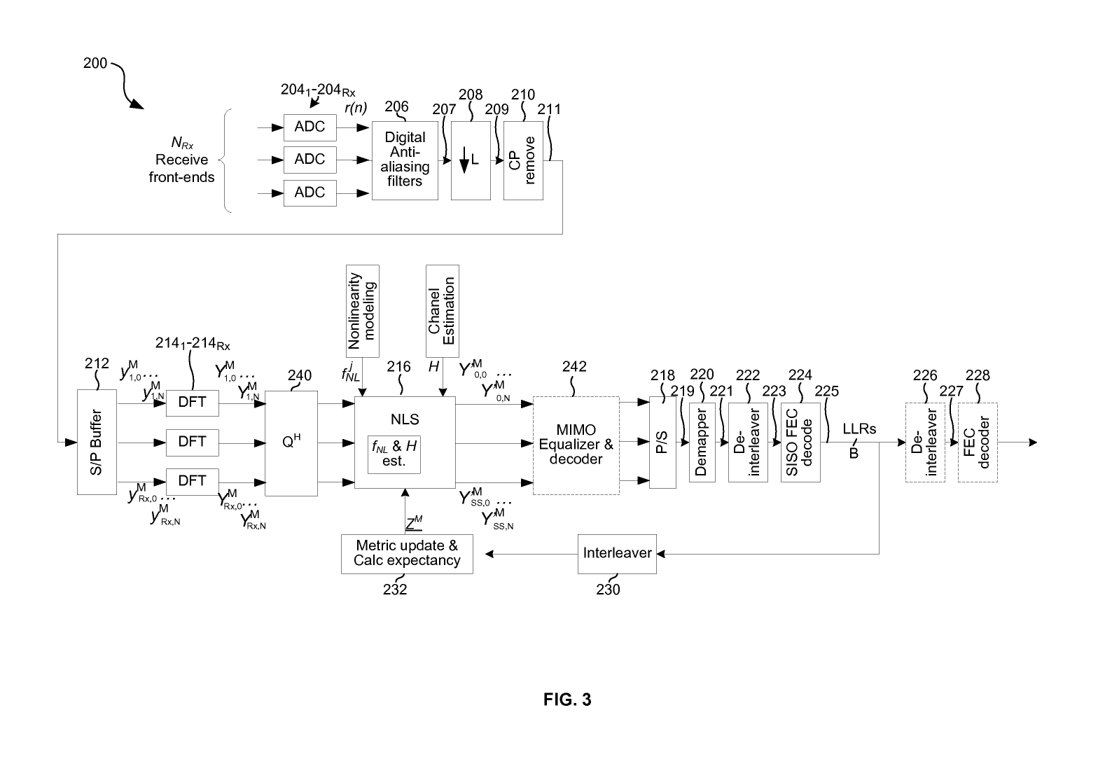

In an OFDM system, allowing the Transmitter's analog front end (AFE) to compress the transmitted signal can significantly reduce the cost and power consumption of the AFE but at the cost of introducing distortion. The distortion introduced can be described as applying a non-linear function ƒ_{NL}(x) to the time-domain transmitted signal x. This distortion is assumed to be known by the receiver, and can be dealt with by through an iterative process. An example transmitter of such a system is depicted in figure FIG. 1 and an example receiver of such a system is depicted in FIG. 3.

‘M’ in FIG. 1 is the OFDM symbol index and ‘N’ is the size of the IDFT 114.

In an example implementation, the Inner FEC encoder 106 codeword size is aligned to IDFT 114 size (i.e. IFT 114 accommodates an integer number of FEC code-words, or FEC code-word size accommodates integer number of FFT's). In an example implementation the inner FEC encoder 106 and Mapper 110 may be merged thereby creating a Euclidean code.

As indicated by the dashed lines, the outer FEC 102 may not be used in some implementations. In this regard, in an example implementation in which the codeword size of the inner FEC encoder 106, which is aligned to the OFDM symbol, is too short to get good coding gain, then the outer FEC encoder 102 may accordingly be used. In such an implementation, the rate of the code may be split between the outer FEC encoder 102 and the inner FEC encoder 106. For example, to get a total code rate of 0.9 the rate of the inner FEC encoder 106 (Rᵢₙ) and the rate of the outer FEC encoder 102 (Rₒᵤₜ) may be set such that Rᵢₙ*Rₒᵤₜ=0.9. In such an implementation, the inner FEC encoder 106 and corresponding SISO (Soft Input Soft Output) FEC decoder 224 (FIG. 3) may be specifically designed for handling nonlinearity. SISO Decoder means that the decode gets soft values at its input and it performs some soft-decision decoding resulting in soft decisions at its output rather than hard bit decisions.

As indicated by the dashed lines, the outer interleaver 104 may not be used in all implementations. In this regard, the outer interleaver 104 may be used in implementations where channel fading is such that it is desired to have a big enough interleaver which spans over several OFDM symbols.

In an example implementation, the FEC 106 may not be aligned IDFT 114. The receiver may be configured to be capable of demodulating non-aligned FEC blocks as explained in the sequel.

In the example transmitter 100 shown, data from a single source or multiple sources is encoded by encoder 106 (or 102 and 106, if 102 is present) and then parsed to N_{SS} spatial streams. In another implementation, the data associated with the different spatial streams may be encoded independently (i.e., via N_{SS} encoders 106 and/or Nss encoders 102).

The bits of the one or more spatial streams are mapped to constellation symbols by mappers 110₁-110_{SS}. Alternatively, a single mapper 110 may be used to map all spatial streams in turn.

In an example implementation where the transmitter 100 has information on the selectivity of the fading channel from transmitter 100 to an intended receiver (e.g., receiver 200 of FIG. 3), the symbol mapper(s) 110 may be used to zero out pairs of subcarriers and MIMO spatial streams that undergo extreme attenuation (e.g., attenuation greater than some threshold amount of attenuation). As used herein, such a subcarrier and stream pair may be referred to as a “bin”, where for example subcarrier 10 of stream 1 is one bin, subcarrier 20 of stream 1 is another bin, subcarrier 2 of stream 2 is another bin, and so on. In another example the symbol mapper(s) 110 may set extremely-attenuated bins to values known to the receiver (i.e. pilots). This is beneficial, for example, in the case of a highly distorted power amplifier (PA) since the extremely attenuated bins contribute very little mutual information to the receiver, while also non-linearly mixing with other bins and increasing their distortion. In particular, the receiver typically tracks the OFDM channel continuously. The receiver may periodically determine those bins being so highly attenuated that they inflict more distortion than contributing useful signal. The receiver then periodically sends a list indicating these bins to the transmitter. In which case the symbol mapper(s) 110 may zero out the transmission signal on those bins. Thus receiver knows the transmitted values on these bins exactly—either zeros or scrambled pilots—for the purpose of computing distortion. The receiver, for the purpose of FEC decoding, may consider the bits carried by these bins as punctured by zeroing out the soft decisions (e.g., log likelihood ratios LLRs) for such bins. In some cases the transmitter 100 may determine by itself the list of bins to zero (e.g. by use of channel reciprocity). In such a case, a more robust packet header may be transmitted including a list of zeroed bins. In an example the more robust packet header uses lower constellations and lower rate and thus can be demodulated without aid of a nonlinear solver (NLS) circuit (such as NLS 216 described below).

The one or more spatial stream(s) is/are mapped to transmit chains where the number of the transmit chains (N_{Tx}) is equal to or larger than the number of spatial streams (N_{SS}). In the example transmitter 100, this mapping is accomplished by an N_{Tx}×N_{SS} spatial mapping matrix V (per each OFDM subcarrier). This matrix, which is implemented by precoder 130 in the example transmitter 100, routes a linear combination of the data of the one or more streams to each transmit chain. The precoder 130 provides some spatial diversity to the transmitted data and the use of multiple data streams which are transmitted concurrently is a MIMO (multiple input multiple output) configuration called spatial multiplexing. This configuration uses multiple transmit chains (each including an antenna in wireless communication) in order to increase the attainable data rate. In order to communicate such a signal associated with N_{SS} independent spatial streams, the transmitter 100 should comprise at least Nss transmit chains. When the number of such transmit chain, N_{Tx}, is larger than the number of spatial streams, N_{SS}, some degree of diversity is achieved along with spatial multiplexing. In general, the precoder matrix V (where bolding is used in this disclosure to indicate vectors and matrices) is derived by the following singular value decomposition (SVD) of the channel response matrix: Ĥ=UDV^{H}, where Ĥ is an estimate of the actual channel response H, for a certain subcarrier frequency, D is a diagonal matrix and U and V are unitary matrices. This decomposition describes the channel as a combination of Eigen modes (spatial directions) associated with some quality factor (value of the singular values on the diagonal matrix D). The frequency-domain signals at the output of the precoder 130 are collected to generate OFDM symbols. These symbols are converted to the time domain by N_{Tx} IDFT (inverse Discrete Fourier Transform) (e.g., implemented using an IFFT algorithm) circuits 114. Another implementation may use a single IDFT circuit 114 that processes and generates, independently, all of the N_{Tx} signals for the N_{Tx} transmit chains, in turn.

The multiple sample streams are processed by N_{Tx} transmitter chains (each comprising a digital to analog converter 126 and an analog front end (including power amplifier) 128) and transmitted onto the channel. According to one embodiment, the amplifiers in 128₁-128_{Tx} in the multiple transmit chains are operated in a relatively non-linear power range. That is, the PAPR (Peak to Average Power Ratio) at the transmitter output is low (relative to conventional OFDM transmitter), e.g., in the range of 3 dB-10 dB.

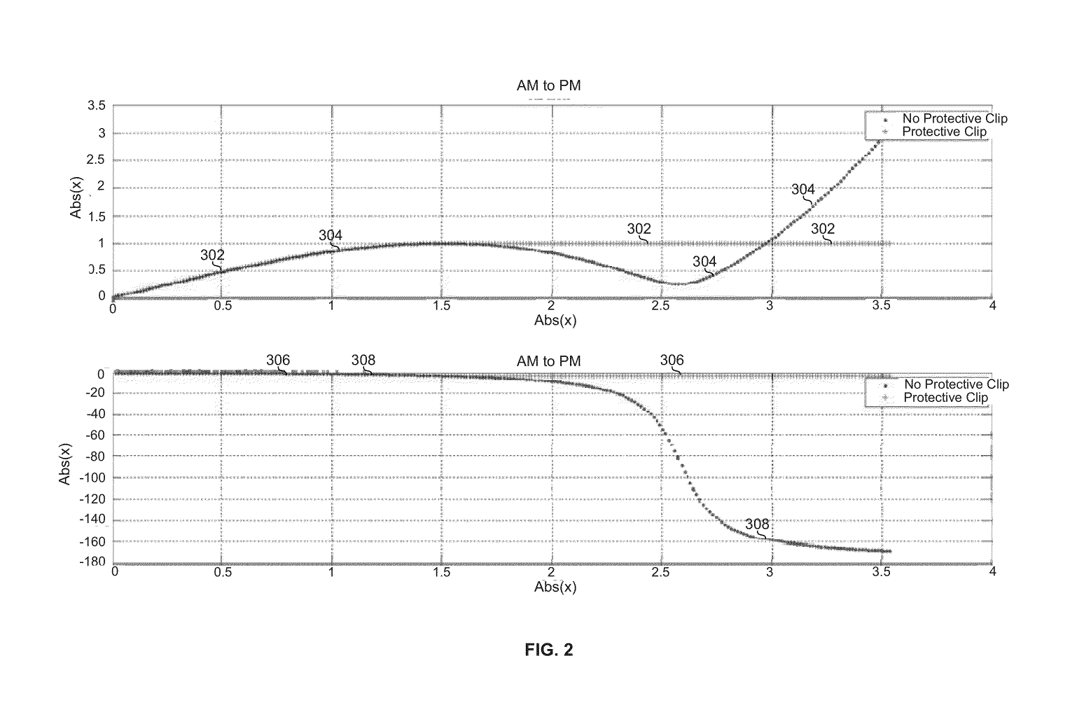

The DNF circuits 124₁-124_{Tx} process the filtered signals output by filtering and/or windowing circuit 122 non-linearly (for example, clipping by a soft limiter) in order to conform to some given spectral limitation and/or to facilitate the reconstruction of the transmitted data in the receiver. Without the digital nonlinear function (DNF) circuitry 124₁-124_{Tx}, the AM to AM characteristic of the PA may not be one-to-one, as depicted by lines 304 and 302 of FIG. 2 (line 304 corresponds to without protective clipping by the DNF circuitry 124, and line 302 corresponds to with protective clipping by the DNF circuitry 124). Lines 306 and 308 of FIG. 2 similarly illustrate the impact of protective clipping by the DNF circuitry 124 on the AM to PM response. The nonlinearity of the DNF circuits 124₁-124_{Tx} may predominate the overall nonlinear characteristic of the transmitter 100 such that the nonlinear characteristic may be substantially-known to a receiver (i.e., known to be substantially equal to the nonlinear characteristics of the DNF circuitry 124), as opposed to the response of the PA which may vary somewhat unpredictably over time. Because the nonlinearity of the transmitted signal is substantially the nonlinearity of the DNF circuitry 124, the DNF circuitry 124 may be configured to have a nonlinearity that simplifies the reconstruction of the data in the receiver through use of the known nonlinearity. Below the clipping threshold (where a “soft clip” is implemented either by the DNF 124 or a separate digital predistortion circuit concatenated with the DNF circuit 124), the response of the DNF 124 may be nonlinear, and, in an example implementation, this nonlinearity may be different than the inverse of the power amplifier (of a respective one of AFEs 128) response below the clipping threshold. Thus, the response of the concatenation of: the DNF circuit 124, a digital predistortion circuit (optional), and power amplifier may be the clipped response above the clipping threshold and may be substantially nonlinear below the clipping threshold (with that substantial nonlinearity being dominated by the response of the DNF circuit 124).

A receiver in accordance with an example implementation of this disclosure is depicted in FIG. 3. The receiver 200 is operable to receive MIMO transmissions with N_{SS} underlying spatial streams. The receiver 200 employs N_{Rx} receive chains such that N_{Rx}≧N_{SS}. Each of the different receive chains comprises an ADC 204. In the example receiver 200 shown, the outputs of the ADCs 2041-204Rx are filtered by anti-aliasing filter 206 and then downsampled in circuit 208 before cyclic prefix removal by circuit 210. The resulting signals N_{Rx} signals are then processed by independent DFT (Discrete Fourier Transform) or FFT (fast Fourier Transform) circuits 214₁-214_{Rx}.

Notation used in FIG. 3 is as follows: M is the OFDM symbol index, N is the size of each of the DFTs 214₁-214_{Rx}, ƒ_{NL} is a model of nonlinearity experienced by the received samples y, H is the estimated transfer characteristic of the channel via which the samples y were received, B is the number of bits per symbol (e.g., B=10 for 1024-QAM), and Z^{M} is a vector of metrics (e.g., a vector comprising \hat{X} (i.e., estimated transmitted subcarrier value which may be, for example, the expectation of X), a quantization of \hat{X} to the nearest point of the constellation that is in use, and/or a minimal bit LLR for each symbol) for OFDM symbol M.

In an example implementation the receiver 200 searches at symbol M for a matrix \hat{X}^{M} having N_{SS} rows and N_{FFT} columns. Where \hat{X}^{M} is an estimate of transmitted signal for symbol M over all spatial streams and subcarriers. This matrix estimation \hat{X}^{M} needs to corresponds to a valid sequence of FEC code words that also minimizes the following cost (over the set of valid code word sequences)

$$\frac{1}{{σ}_{v}^{2}} {\sum }_{i = 1}^{{N}_{Rx}} {‖ {Y}_{i , :} - {\sum }_{j = 1}^{{N}_{Tx}} {\hat{H}}_{i , j , :} \cdot DFT ( {{f}_{NL}^{j} [ IDFT ( {\sum }_{s = 1}^{{N}_{SS}} {V}_{j , s , :} \cdot {\hat{X}}_{s , :} ) ]}_{n} ) ‖}^{2} , \qquad ( 1 )$$

where:
\hat{X}, the estimated transmitted signal, is a N_{SS}×N_{NFFT} matrix, where N_{FFT} is the number of subcarriers (FFT size);
\hat{X}_{S,:} is the s^{th} row of \hat{X};
Y is the observed signal in frequency domain, which is an N_{Rx}×N_{FFT} matrix;
Y_{i,:} is the i^{th} row of Y;
σᵥ² is the noise power, which in (1) is assumed to be white but which could be replaced with noise variance that is indexed by subcarrier and receive antenna to account for frequency and spatially selective noise;
Ĥ_{:,:,k}, for 0≦k≦N_{FFT}−1, is the N_{Rx}×N_{Tx} channel estimation matrix for subcarrier k, and Ĥ_{i,j,k} is channel response matrix from transmitter j to receiver i for subcarrier k;
V_{:,:,k}, for 0≦k≦N_{FFT}−1, is the N_{Tx}×N_{SS} precoder matrix for subcarrier k, and V_{j,s,k} is the transfer from the s^{th} stream to the j^{th} transmit chain of subcarrier k;
ƒ_{NL}^{j} for 1≦j≦N_{TX}, is the nonlinear response of the j^{th} transmit chain (either known to the receiver as a result of being transmitted by the transmitter in control/setup traffic or estimated by the receiver as [symbol] ( ));
the matrix norm is chosen to be the Frobenius norm;
The IDFT/DFT represents IDFT/DFT operations operating on the input samples of size N_{FFT}.

In an example implementation, some of the bins in \hat{X}^{M} are known in advance. There is therefore no need to search for them and they may instead be held fixed. In an example implementation, some of the bins are known to be zeros (e.g. out-of-band and guard band bins). In an example implementation, some of the bins are known to be pilots having a known scrambling sequence.

The MIMO receiver of FIG. 3 employs a rotation operation applied to the received signal and channel estimate in order to streamline the detection. For example, per subcarrier, the output Y of the DFT(s) 214 may be multiplied, in rotator circuit 240, by a transmit chain matrix Q^{H} derived from the following QR decomposition: QR=ĤV, where Ĥ is the estimated channel response matrix. The QR transformation is intended to convert the estimated channel matrix ĤV to a triangular (and possibly diagonal) matrix Q^{H}ĤV. This new channel response matrix is identified with the rotated signal vector Q^{H}Y. The rotator circuit 240 may carry out this rotation of the received signal per each subcarrier independently of the other subcarriers. This may streamline the detection of the MIMO signal, especially when closed-loop MIMO configuration is used such that the off-diagonal entries of the equivalent channel response matrix Q^{H}ĤV are relatively small.

Thus rotator circuit 240 outputs a rotated version of the FFT output at each subcarrier Q^{H}Y. The output of rotator 240 is processed by the NLS circuit 216 such that the transmitted symbols over each subcarrier are detected and soft values are provided to the FEC decoder 224. For example, the cost function of Eq. (1) may be re-written in terms of the Q rotated signal as shown in (2).

$$\frac{1}{{σ}_{v}^{2}} {\sum }_{i = 1}^{{N}_{Rx}} {‖ {\tilde{Y}}_{i , :} - {\sum }_{j = 1}^{{N}_{Tx}} {{h}^{\hat{\sim}}}_{i , j , :} \cdot DFT ( {{f}_{NL}^{j} [ IDFT ( {\sum }_{s = 1}^{{N}_{SS}} {V}_{j , s , :} \cdot {\hat{X}}_{s , :} ) ]}_{n} ) ‖}^{2} , \qquad ( 2 )$$

where: \tilde{Y}=Q^{H}Y and {circumflex over (\tilde{H}=Q^{H}Ĥ are the Q rotated observation and channel estimation matrix, respectively.

In an example implementation, the receiver 200 finds \hat{X} by iterating between the NLS 216 and SISO (Soft-In-Soft-Out) FEC decoder 224. The NLS 216 minimizes the equation (1) (or equation (2)) error based on the output 225 of SISO FEC (“inner FEC”) decoder 224, and also using the channel observation output by rotator circuit 240. The SISO FEC decoder 224 then computes soft-decisions (e.g., LLRs) based on NLS 216 output. These iterations are called “outer” iterations and are repeated until decoding condition is met (e.g., a particular performance threshold is reached, a particular iterations limit is reached, and/or the like). In an example implementation, the NLS 216 may do several “inner” iterations per outer iteration, for the purpose of minimizing (1) (or (2)). In an example implementation, the FEC decoder 224 may do several “inner” iterations per outer iteration for the purpose of computing soft decisions.

To simplify notation, and reduce the number of indices, in the remainder of this disclosure (except where otherwise specified) the 3D matrices are reformulated as 2D sparse “blocks diagonal” matrices. Similarly, since cost functions (1) and (2) have identical form, and therefore can be treated the same, the remainder of this disclosure we will only consider cost function (1). Using the block diagonal formulation, the following cost function (3) is obtained (and is completely equivalent to (1)).

$$\frac{1}{{σ}_{v}^{2}} {‖ Y - \hat{H} \cdot DFT ( {f}_{NL} ( IDFT ( V \cdot \hat{X} ) ) ) ‖}^{2} ≡ \frac{1}{{σ}_{v}^{2}} {\sum }_{i = 1}^{{N}_{Rx}} {‖ {Y}_{i , :} - {\sum }_{j = 1}^{{N}_{Tx}} {\hat{H}}_{i , j , :} \cdot DFT ( {{f}_{NL}^{j} [ IDFT ( {\sum }_{s = 1}^{{N}_{SS}} {V}_{j , s , :} \cdot {\hat{X}}_{s , :} ) ]}_{n} ) ‖}^{2} , \qquad ( 3 )$$

where:
\hat{X}=[\hat{X}_{1:N}_{_{SS}}_{,0}^{T}, \hat{X}_{1:N}_{_{SS}}_{,1}^{T}, . . . , \hat{X}_{1:N}_{_{SS}}_{,N}_{_{FFT}}₋₁^{T}]^{T}, which is a N_{SSBINS}×1 vector, is obtained by stacking up \hat{X}_{:,k} for all subcarriers k. Thus \hat{X}(s−1+[0:N_{FFT}−1]·N_{SS}) corresponds to subcarriers of stream s.
N_{SSBINS}=N_{SS}·N_{FFT} represents the aggregate number of subcarriers in all spatial streams
Y=[Y_{1:N}_{_{RX}}_{,0}^{T}, Y_{1:N}_{_{RX}}_{,1}^{T}, . . . , Y_{1:N}_{_{RX}}_{,N}_{_{FFT}}₋₁^{T}]^{T}, which is a N_{RXBINS}×1 vector, is obtained by stacking up Y_{:,k} for all subcarriers k.
N_{RXBINS}=N_{RX}·N_{FFT} represents the aggregate number of subcarriers over all receive antennas
N_{TXBINS}=N_{TX}·N_{FFT} represents the aggregate number of subcarriers over all transmit antennas
Ĥ is a (N_{RX}·N_{FFT})×(N_{TX}·N_{FFT}) channel estimation matrix, where Ĥ=0 except for the elements Ĥ(k·N_{RX}+(0:N_{RX}−1), k·N_{TX}+(0:N_{TX}−1))=Ĥ_{1:N}_{_{RX}}_{,1:N}_{_{TX}}_{,k}, for kε0 . . . N_{FFT}−1
V is a (N_{TX}·N_{FFT})×(N_{SS}·N_{FFT}) precoding matrix, where V=0 except for the elements (k·N_{SS}+(0:N_{SS}−1), k·N_{TX}+(0:N_{TX}−1))=V_{1:N}_{_{SS}}_{,1:N}_{_{TX}}_{,k}, for kε0 . . . N_{FFT}−1
ƒ_{NL} is a vector of N_{Tx} nonlinear functions capturing the nonlinear behavior of the N_{Tx} transmit chains. I.e.

ƒ_{NL}(x)|ₙ=ƒ_{NL}^{1+(n mod N}^{_{Tx}}⁾(x_{(n mod N}_{_{Tx}}_{)+[0:N}_{_{FFT}}_{-1]·N}_{_{Tx}})|_{└n/N}_{_{Tx}}_{┘}
where: 1+(n mod N_{Tx}) represents the index of the TX antenna, and x_{(n mod N}_{_{Tx}}_{)+[0:N}_{_{FFT}}_{-1]·N}_{_{Tx}} is the set of time samples for the corresponding antenna
IDFT/DFT represent N_{Tx} IDFT/DFT operations operating on the input samples of each one of the transmitters. I.e.

$$IDFT ( X ) {\vert}_{n} ≡ \frac{1}{{N}_{FFT}} {\sum }_{k = 0}^{{N}_{FFT} - 1} X ( ( n mod {N}_{Tx} ) + k \cdot {N}_{Tx} ) {e}^{\frac{j 2 π k ⌊ n / {N}_{Tx} ⌋}{{N}_{FFT}}} \\ DFT ( x ) {\vert}_{k} ≡ {\sum }_{k = 0}^{{N}_{FFT} - 1} x ( ( k mod {N}_{Tx} ) + n \cdot {N}_{Tx} ) {e}^{\frac{- j 2 π k ⌊ n / {N}_{Tx} ⌋ n}{{N}_{FFT}}}$$

where: (k mod N_{Tx}) and (n mod N_{Tx})—where mod==modulo, both represent the index of the TX antenna minus 1, and [k/N_{Tx}] and [n/N_{Tx}] where [a] is floor operation on a, represent the subcarrier and sample time indices of the corresponding TX antenna.

In an example implementation, the equalization and MIMO decoder 242 may be omitted in which case the output of NLs circuitry 216 is used directly by the demapper 220. In such an implementation, the estimates of the transmitted symbols generated by the NLS circuitry 216, \hat{X}, are used through demapper 220 to derive the soft values (e.g., LLRs) to the FEC decoder 224.

In another embodiment, the MIMO equalizer and decoder 242 may be used in order to utilize the information generated by the NLS circuit 216. In this implementation, the MIMO equalizer and decoder 242 operates on a per-subcarrier basis. The input to the MIMO equalizer and decoder 242 is the estimated symbol for that subcarrier over all spatial streams, (e.g., \hat{X}_{1:N}_{_{SS}}_{,k} for subcarrier k) as well as the noise covariance matrix for that subcarrier (e.g., Λₖ for subcarrier k) as estimated by the NLS circuit 216, where the (i,j)-entry of that matrix is the estimated covariance of the noise components over the i^{th} and j^{th} streams of the k^{th} subcarrier. The symbol estimates in addition to the noise covariance matrix are used to generate soft values (e.g., LLRs) through demapper 220 by calculating the cost function (or a variant thereof) of (5) for multiple candidates A_{1:N}_{_{SS}}_{,k}^{(l)}:

(\hat{X}_{1:N}_{_{SS}}_{,k}−A_{1:N}_{_{SS}}_{,k}^{(l)})^{H}Λₖ⁻¹(\hat{X}_{1:N}_{_{SS}}_{,k}−A_{1:N}_{_{SS}}_{,k}^{(l)})^{H}; l=0,1, . . . ,L−1 (4)

where L denotes the number of candidates visited by the MIMO decoder in order to derive a list of the probable (low cost) symbol Nₛₛ-tuples that best match the input estimate vector \hat{X}_{1:N}_{_{SS}}_{,k} and noise covariance matrix. This number of candidates may be subcarrier index-dependent or vary according to the processed data (estimated symbol N_{SS}-tuple and noise covariance matrix). This list of Nₛₛ-tuple candidate symbols may be used by the demapper 220 or directly by the MIMO Equalizer & decoder 242 to generate soft-values (per-bit of each one of the Nₛₛ symbols communicated over the processed subcarrier) which are then fed to the FEC decoder 224. As a MIMO equalizer and decoder 242 one may use any suitable decoding technique such as sphere decoding, list decoding, successive interference cancellation, linear MIMO decoding, and/or any other suitable decoding technique. It is noted that the NLS circuitry 216 exploits the dependencies induced by the nonlinearity on the different subcarriers. In an example implementation, the NLS circuitry 216 may use a simplified cost function that does not totally account for the correlation between the noise components over the different spatial streams. Instead, the extraction of the dependencies between the different special streams of the same subcarrier, under the restriction that the transmitted symbols must take on a value from a known constellation grid, may be relegated to the MIMO Equalizer & decoder according to the scheme described herein.

In another embodiment, the MIMO equalizer and decoder 242 may be used along with a cost function that accounts for the nonlinear model of the transmitter (e.g., Eqs. (1)-(3)). In other words, by contrast to prior art MIMO Equalizer and Decoder, a MIMO Equalizer and Decoder according to this embodiment works on a distorted space and calculates a measure of likelihood of some list of candidates on that space that captures the nonlinear characteristic of the transmitter. For example, the MIMO Equalizer and Decoder can take the estimate found by the NLS machine, \hat{X}_{1:N}_{_{SS}}_{,k}, and search in some vicinity of that solution, per subcarrier, for constellation points that achieve relatively low cost under the nonlinear model (Eqs. (1)-(3)). These candidates may be found by some gradient method, searching for points for a single subcarrier at a time, setting the rest to the values found by the NLS machine. The list of candidates, per each subcarrier, are used by the MIMO Equalizer and Decoder or by the subsequent Demapper in order to calculate the LLR values for the constituent bits.

In an example implementation, ƒ_{NL} (including the components for N_{Tx} different power amplifiers) is updated according to the rate at which characteristics of the analog front ends 128 (e.g., comprising a power amplifier and, in some instances, an upconverter) change. In an example implementation, ƒ_{NL} may be updated each OFDM symbol, or once per every few OFDM symbols. In an example implementation in which burst transmissions are used, ƒ_{NL} may be updated at start of each burst. In an example implementation, ƒ_{NL} may be adapted using dedicated preambles or beacon patterns that are generated once in a while (e.g., periodically, pseudo-randomly, and/or the like) by the transmitter. In an example implementation, ƒ_{NL} may be adapted based on \hat{X} and/or other metrics calculated based on the LLRs output by FEC decoder 224, as further described below.

### MIMO Cost Minimization

In an example implementation the receiver 200 finds \hat{X} by iterating between the NLS 216 and SISO FEC decoder 224. In order to impose FEC constraints on the NLS circuitry 216 we a correction term ΔX is introduced and applied to a previous FEC estimate \hat{X}. The cost function (3) is augmented to constrain the correction in the following way (this applies similarly to cost function (2)). Every outer iteration, the NLS 216 needs to find an N_{SSBINS}=N_{SS}×N_{NFFT} correction matrix ΔX that minimizes the frequency-domain cost function (5).

$$\frac{1}{{σ}_{v}^{2}} {‖ Y - \hat{H} \cdot DFT ( {f}_{NL} ( IDFT ( V \cdot ( \hat{X} + Δ X ) ) ) ) ‖}^{2} + {\sum }_{k = 0}^{{N}_{SSBINS} - 1} \frac{{\vert Δ {X}_{k} \vert}^{2}}{{σ}_{k}^{2}} \qquad ( 5 )$$

where:
N_{SSBINS} is the aggregate number of subcarriers over all spatial streams
∥·∥ denotes the Frobenius norm of a vector.
Y is the observed signal in frequency domain, over all RX antennas
Ĥ is the block diagonal channel estimation matrix, over all bins, RX antennas, and TX antennas
ƒ_{NL}(x) is the overall nonlinear response experienced by signals received by the receiver. In an example implementation this may be dominated by non-linear response of the transmitter (e.g., the response of the AFE 128 and/or the response of the DNF circuitry 124) as depicted in FIG. 2 (AM to AM distortion and AM to PM distortion). It can be implemented, for example, as a mathematical computation or a Look Up Table (LUT)
\hat{X}ₖ is the estimated transmitted bin k (e.g., calculated as the expectation of X), which corresponds to spatial stream s=k mod N_{SS}, and subcarrier [k/N_{SS}]
X is a N_{SSBINS}×1 vector that aggregates transmitted bins over all spatial streams (input of IDFT 114 in FIG. 1)
\hat{X} is a N_{SSBINS}×1 vector whose elements are \hat{X}ₖ;
ΔXₖ is an estimation of the error at bin k (i.e., element k of the vector X−\hat{X});
ΔX is a N_{SSBINS}×1 vector whose elements are ΔXₖ;
σᵥ² is the noise floor (in frequency) here assumed to be uniform over antennas and subcarriers, but may be made subcarrier and RX antenna dependent in other implementations
h is the channel response; and
σₖ² is the reliability measure for bin \hat{X}ₖ. That is, when there is high reliability estimate for bin k, then it would be reflected in the cost function as a small σₖ² in order to induce relatively high penalty to deviations from this estimate. In an example implementation, σₖ² may be set to the variance of \hat{X}ₖ. In an example implementation, σₖ² may be a function of LLRs output by the SISO FEC decoder 224 (e.g., a function of the inverse of the min(|LLR|). In an example implementation, when σₖ² is below some determined threshold for a particular symbol, it may be set to ∞ for that symbol to indicate the symbol is bad.

The receiver uses outer iterations where, at each iteration, an estimation of ΔXₖ (for one or more values of k) that minimizes the cost function (5) is produced by NLS circuitry 216 and re-fed to the FEC decoder 224. The cost function need not necessarily find the best solution for ΔXₖ, but need only find new value of ΔXₖ that reduces the cost, while providing information that is extrinsic to the FEC decoder 224. This refinement is iteratively used in the FEC decoder 224 to further distill \hat{X}. This iterative scheme uses the nonlinear cost function (5)—including ƒ_{NL} and MIMO channel—as an inner code in conjunction with an outer FEC code. The NLS circuitry 216 uses constraints, such as those shown in (5), on the frequency domain signal to aid in generation of its output, and the decoder 224 similarly imposes FEC code constraints on the frequency domain signal, as discussed below, to aid in generation of its output. Each one of the NLS circuitry 216 and the FEC decoder 224 uses a refinement of the data estimation generated by the other in order to improve its own estimate based on different, independent constraints in an iterative scheme.

In an example implementation, \hat{X} is estimated by the metric update block 232 by calculating \hat{X} using LLR's from the SISO FEC decoder 224 (“mapping” the LLR's). In an example implementation \hat{X} the expectation based on the LLR's.

In an example implementation the cost function (5) is minimized by use of gradient descent to find all or a subset of the bin corrections ΔXₖ. In an example implementation, ΔXₖ may be estimated for all bins during each iteration.

In an example implementation, only those bins for which the confidence of being erroneous is high (e.g., based on LLRs output by the SISO FEC decoder 224) may be estimated during a particular iteration and other bins, referred to here as “good,” (e.g. those bins having a decoded LLR above a determined threshold) may be fixed based on an assumption that the output of FEC decoder 224 is correct. The ΔXₖ for good bins may, for example, be fixed at a value of zero while adapting the ΔXₖ for the other bins.

The values of X are limited to some constellation χ (e.g. 1024QAM). Therefore the estimation may be constrained to the same constellation (i.e. (\hat{X}ₖ+ΔXₖ)εχ). This, however, results in a very difficult discrete minimization problem. To overcome this difficulty, in one example implementation, \hat{X}ₖ+ΔXₖ is limited to a rectangular range (|re(\hat{X}ₖ+ΔXₖ)|≦Xₘₐₓ and |im(\hat{X}ₖ+ΔXₖ)|≦Xₘₐₓ) that includes the constellation χ, this is called the hard bound approach. The down side of this approach is that gradient descent convergence is slowed down by the hard bounds. Accordingly, in an example implementation, soft bounds may be used as an additional penalty term to the cost function (e.g., values of \hat{X}ₖ+ΔXₖ outside the constellation rectangle are penalized with a penalty increasing with distance from the constellation rectangle, as shown in equation (6) below).

(|re(x)|>Xₘₐₓ)(|re(x)|−|Xₘₐₓ|)²+(|im(x)|>Xₘₐₓ)(|im(x)|−|Xₘₐₓ|)² (6)

where:
Xₘₐₓ—Is maximum constellation value (e.g. 31 for 1024 QAM)
(a>b)—evaluates to 1 if the condition is true and zero otherwise.

Referring back to FIG. 3, for this second example implementation of the NLS circuitry 216, Y′^{M} output by the NLS circuitry 216 may be equal to \hat{X}^{M}+ΔX^{M}.

In an example implementation in which phase noise is negligible, H may be a purely block diagonal matrix with N_{RX}×N_{TX} blocks on the diagonal. In an example implementation, the matrix H may comprise off-diagonal block that account for Inter-Carrier Interference, to compensate for phase noise and/or any other Inter-Carrier Interference (e.g. caused by fast varying channel).

### Splitting the Problem to Two Dimensions

In an example implementation, to increase the diversity of the cost with respect to “good” decision errors we may minimize real(X) and imag(X) as separate variables. This allows performance improvement by deciding on the reliability of single bin dimension (i.e. good/bad decisions taken separately on bin real part and separately on bin imaginary part), rather than the reliability of complex bins (e.g., for a certain bin Xₖ the real part may be considered bad and take part in minimization, while the imaginary part may be considered good and kept fixed).

Hard Metric Vs. Soft Metric

As mentioned above, the 2nd term in equation (5) indicates the reliability of bin Xₖ. When σₖ² is close to 0, the cost would only allow using values of ΔXₖ which are very small.

In an example implementation, the second term may be dropped from equation (5). Instead, the NLS circuitry 216 may determine which of the elements in \hat{X} are reliable, (denoted as “good” bins) and which elements in \hat{X} are unreliable (“bad” bins) and operate as follows: During the 1st iteration on an OFDM symbol m, the NLS circuitry 216 may assume that all bins are bad bins (except of those corresponding to out of band zeros and pilot), and then search for N_{SSBINS} ΔXₖ elements (or 2·N_{SSBINS} ΔXₖ elements if working independently on real and imaginary dimensions). Then, in later iterations, the NLS circuitry 216 may get information from the metric update block 232 which enables the NLS circuitry 216 to lower the number of ΔXₖ elements in the search (i.e. fix the good bins to constant values), and the problem boils down to finding the bad bins that minimize the cost. Thus, the NLS circuitry 216 may search for N_{bad} (where N_{bad}<N_{SSBINS}) ΔXₖ elements corresponding to the N_{bad} bad bins. In such an implementation, the hard metric cost function may be as shown in equation (7).

∥Y−H·DFT(ƒ_{NL}(IDFT(\tilde{X})))∥² (7)

where:

$${\tilde{X}}_{k} = \{ \begin{matrix}{\hat{X}}_{k} & when {θ}_{k} < TH \\ {\hat{X}}_{k} + Δ {X}_{k} & otherwise\end{matrix}$$

TH is a threshold for selecting the good bins. In an example implementation, the NLS circuitry 216 determines good/bad by comparing the metric θₖ to a threshold TH (e.g., if θₖ<TH then bin k is considered a good bin). In an example implementation, the threshold TH is fixed at a determined value. In another example implementation, described below, TH may be dynamically configured.
θₖ is a metric that is used to determine if a bin is a good bin or a bad bin. The metric θₖ is determined by metric update block 232. In an example implementation, θₖ=σₖ². In an example implementation, the metric update block 232 maps the interleaved LLRs {LLRₖ^{l}} for bin k, to produce its estimate \hat{X}ₖ, and also computes the metric

$${θ}_{k} = - {min}_{l} \{ \vert {LLR}_{k}^{l} \vert \} .$$

In other words, NLS circuitry 216 may determine the bin to be good if the absolute value of the minimal LLR in the bin is higher than a threshold. For example, for a 1024-point symbol constellation there may be 10 LLRS per symbol and the minimal LLR may be the smallest of the 10. In an example implementation, to increase diversity, the NLS circuitry 216 may determine good and bad per bins dimension, (e.g. the real part of a particular bin can be declared “good” while the imaginary part of the particular bin may be determined to be “bad”). For example, for 1024QAM there may be 10 LLRS per symbol with the first 5 of them corresponding to the real component and the second 5 of them corresponding to the imaginary component, and the NLS circuitry 216 may determine the smallest LLR of the first 5 and the smallest LLR of the second 5.

### Updating Good Selection Threshold (“Gears”)

In an example implementation, the threshold TH is set dynamically (per iteration and codeword) according to some percentile P of the set of metrics {θₖ|k=1 . . . 2N_{cw}_{_{—}}_{bins}}, where the factor of two arises from treating the real and imaginary dimensions separately, computed per codeword based on latest FEC decoding, where N_{cw}_{_{—}}_{bins} is the number of QAM symbols (i.e. bins) composing the FEC codeword (i.e. the most reliable P % of the set of real and imaginary values of the bins are selected as goods). That is, the sequence of sorted metrics shown in equation (8) may be calculated for each codeword.

(θₛ)_{s=1 . . . 2N}_{_{cw—bins}}=sort({θₖ|k=1 . . . 2N_{cw}_{_{—}}_{bins}}) (8)

The sorting may be performed in increasing order (i.e. starting with θₛ₌₁, which is the most-reliable bin and ending with θ_{s=2N}_{_{cw—bins}}, which is the least reliable). Per codeword and iteration, the NLS circuitry 216 may set TH=θ_{s=P·2N}_{_{cw—bins}}. For each subsequent iteration on the same codeword, and for the next codeword, the NLS circuitry 216 may again sort the metrics and set the threshold based on the P^{th} percentile.

In an example implementation where the decisions as to which bins are good and which are bad is made per complex bin (rather than separately for the real and imaginary dimensions) the metrics {θₖ|k=1 . . . N_{cw}_{_{—}}_{bins}} may be determined per bin and a similar selection process for the threshold TH may be used.

In an example implementation the percentile P used for determining the threshold TH is also changed as the iterations progress. In one example the percentile P may be iteration dependent (i.e. P←Pᵢₜₑᵣ).

### Using “Branches”

For the hard metric case, mistaking a bin dimension (i.e. real dimension or imaginary dimension) that contains erroneously decoded bits as “good” might result in performance reduction, since the good bin dimensions are not corrected by the NLS circuitry 216 (although the FEC decoder 224 may still correct these bits). This problem may be overcome, in one example, by the NLS circuitry 216 assuming we have total of N_{g} good bin dimensions and running N_{g}+1 times per codeword in the following way: In order to estimate the real and/or imaginary bin dimensions that are bad, the NLS circuitry 216 runs once to minimize the cost function of equation (5) by optimizing ΔX_{kεbads} while the correction for all the good bins dimensions is fixed to zero (i.e., ΔX_{kεgood}=0). Then, for each good bin dimension, (mεgood) the NLS circuitry 216 runs again to minimize the same cost function by optimizing ΔX_{kε{m}∀bads} while setting ΔX_{kεgood-{m}}=0, from which only the m^{th} bin dimension correction (i.e. ΔXₘ) is used. Since in this case NLS circuitry 216 is run to obtain both the good bin dimensions as well as the bad bin dimensions, the outer iterations can effectively handle false goods.

In an example implementation, the NLS circuitry 216 may run fewer times per codeword by dividing the good bin dimensions into N_{B} non-overlapping sets called “branches” B_{b} such that good bins=∪_{b=1}^{N}^{_{B}}B_{b}. In an example implementation, the sets may be of approximately the same size. Then the NLS circuitry 216 may run N_{B}+1 times per codeword. In order to estimate the bad bin dimensions, the NLS circuitry 216 runs once, as before, to minimize cost by optimizing ΔX_{kεbads} with correction for all the good bin dimensions fixed to zero (i.e., ΔX_{kεgood}=0). Then, for each branch B_{b} (with b=1, . . . , N_{B}) the NLS circuitry 216 is run again to minimize cost by optimizing ΔX_{kεB}_{_{b}}_{∪bads} while setting ΔX_{kεgood-B}_{_{b}}=0, from which only the branch B_{b} bin dimensions corrections (i.e. ΔX_{kεB}_{_{b}}) are used.

In an example implementation, the same branch scheme may be used, but using only one branch (i.e. using b=1). In this implementation, the NLS circuitry 216 may run only twice per codeword—once to estimate all bad bin dimensions (ΔX_{kεbads}) using the good ones, and a second time to estimate the good bin dimensions (ΔX_{kεgood}) without fixing any correction to zero (i.e. all ΔXₖ are optimized but only output ΔX_{kεgood} is used).

In an example implementation, the percentile P may be increased when the NLS circuitry 216 determines that the number of false good bin dimensions (mistakenly identified as good bin dimensions) for previous iterations is low. This may be based on the latest iteration for branches. In an example implementation, a sequence of successive P values ({Pₗ}_{l=1 . . . L}) is used. The NLS circuitry 216 initially starts with 0 good bin dimensions, but after the first iteration uses Pₗ·N_{cw}_{_{—}}_{bins} good bin dimensions for l=1. Then, for each additional outer iteration, the NLS circuitry 216 increases l if the latest branch corrections (|ΔX_{kεgood}|) are small enough. In an example implementation, the NLS circuitry 216 may compare the sum (or average) of absolute branch correction Σ_{kεgood}|ΔXₖ| to a threshold, and increase if the sum (or average) is below the threshold. In an example implementation, the NLS circuitry 216 compares the sum (or average) of some monotonically increasing function ƒ(·) of absolute branch corrections (i.e. Σ_{kεgood}ƒ(|ΔXₖ|)) to a threshold, and increases l if the sum (or average) is below the threshold. In an example implementation, the NLS circuitry 216 may use ƒ(|ΔXₖ|)=|ΔXₖ|⁴. In an example implementation, the NLS circuitry 216 may divide the good bin dimensions into P groups and for each 1≦q≦P compute the metric Σ_{kεgood}_{_{—}}ₚƒ(|ΔXₖ|), and increase the good percentage P_{q} specific to that group. In an example implementation, the two groups may be the real and imaginary parts of the bin symbols (i.e. one group being all the real dimensions and the other group being all the imaginary dimensions). In an example implementation, the NLS circuitry 216 may replace the branch correction ΔXₖ with the difference between latest output of FEC decoder 224 to previous output of NLS circuitry 216 for the good bin dimensions. In an example implementation, the NLS circuitry 216 may replace the branch correction ΔXₖ by the difference between latest output of the FEC decoder 224 and the previous input to the NLS circuitry 216 for the good bin dimensions. In an example implementation, the NLS circuitry 216 may use a combination of the previous differences between input of NLS circuitry 216, output of NLS circuitry 216, and latest output of FEC decoder 224.

In an example implementation, a single instance of NLS circuitry 216 is used but still applies a limited correction to the good bin dimensions by taking advantage of the iterative nature of the NLS circuitry 216, which may use inner iterations (not to be confused with outer iterations involving the FEC decoder 224). The inner iterations of the NLS circuitry 216 change only the bad bin dimensions without changing the good ones. On each inner NLS iteration, the gradient of the good bin dimensions (typically costing no additional complexity) is computed, but without updating the good bin dimensions. After completing the NLS inner iterations, another gradient descent step is performed using the mean of the good gradient (averaged per-bin dimension over all NLS inner iterations) this time updating the good bin dimensions. In an example implementation, this gradient step is incorporated into the last NLS inner iteration. In this case, the percentile P may be determined defining ΔXₖ as NLS correction to the good bin dimensions (as opposed to previously using the branch correction).

### Solving the Update Metric

In an example implementation, the NLS circuitry 216 finds the ΔX which minimizes the cost function (5) using an iterative scheme. In an example implementation, the NLS circuitry 216 uses a gradient decent algorithm (GD).

There are two basic kinds of nonlinearity models: with memory, and without memory. Memoryless power amplifiers are completely characterized by their AM/AM (Amplitude to Amplitude) and AM/PM (Amplitude to Phase) conversions which depend only on the current input signal value.

The following gradient derivation deals with memoryless PA, examples for PA with memory can be found in U.S. patent application Ser. No. 14/809,408, which is hereby incorporated herein by reference in its entirety. The gradient can be used to minimize the cost function repeated here omitting 1/σᵥ². For the purpose of gradient derivation the receiver 200 may use the cost function (1) formulation and not the block diagonal formulation.

$${C}_{MIMO} = {\sum }_{i = 1}^{{N}_{Rx}} {‖ {Y}_{i , :} - {\sum }_{j = 1}^{{N}_{Tx}} {\hat{H}}_{i , j , :} \cdot DFT ( {{f}_{NL}^{j} [ IDFT ( {\sum }_{m = 1}^{{N}_{SS}} {V}_{j , m , :} \cdot {\hat{X}}_{m , :} ) ]}_{n} ) ‖}^{2} \qquad ( 9 )$$

Where ƒ^{j}_{NL}(x) is a scalar complex=>complex function modeling the j^{th} memoryless PA non-linear response. ƒ^{j}_{NL}(x) are not necessarily analytical; and jε1 . . . N_{Tx}

Given this memoryless PA model, the receiver 200 can implement the gradient descent with O(N*log N) complexity (where O is a positive number). The gradient has the form shown in (10):

$$\frac{\partial {C}_{MIMO}}{\partial Re ( {X}_{m} )} + j \frac{\partial {C}_{MIMO}}{\partial Im ( {X}_{m} )} == 2 {\sum }_{i = 1}^{{N}_{Rx}} {\sum }_{j = 1}^{{N}_{Tx}} ( DFT ( {( {\frac{\partial {f}_{j}}{\partial X} [ IDFT ( {\sum }_{m = 1}^{{N}_{SS}} {V}_{j , m} \cdot {X}_{m} ) ]}_{n} )}^{*} {IDFT ( {H}_{i , j}^{*} \cdot {E}_{i} ( X ) )}_{n} ) \cdot {V}_{j , m}^{*} + DFT ( ( {\frac{\partial {f}_{j}}{\partial {X}^{*}} [ IDFT ( {\sum }_{m = 1}^{{N}_{SS}} {V}_{j , m} \cdot {X}_{m} ) ]}_{n} ) {( {IDFT ( {H}_{i , j}^{*} \cdot {E}_{i} ( X ) )}_{n} )}^{*} ) \cdot {V}_{j , m} ) , \qquad ( 10 )$$

where:

$${E}_{i} {=}^{Δ} {Y}_{i} - {\sum }_{j = 1}^{{N}_{Tx}} {H}_{i , j} \cdot DFT ( {{f}_{j} [ IDFT ( {\sum }_{m = 1}^{{N}_{SS}} {V}_{j , m} \cdot {X}_{m} ) ]}_{n} ) \qquad ( 11 )$$

The above derivation is directly applicable to cost function (2) where QR rotation transformation is applied to the received signal. In such case, Y and H in Eqs. (9)-(11) should be replaced by their rotated counterparts, QHY and R=QHH, respectively. In Eq. (11), the superscript (k) stands for the subcarrier index.

The above minimization may be carried out jointly over all of the spatial streams. Alternatively, nonlinearity accommodating approaches for single input single output (SISO) systems may be used in conjunction with some “layered” MIMO detector (e.g., successive interference cancellation (SIC) detector) in order to solve the problem, stream by stream. Such approaches may use some channel state information in order to decide on the solution order of the different streams. In general, the minimization is not restricted to take on only values on the constellation grid. However, for MIMO it may be beneficial to combine the “soft-value” minimization problem with MIMO detection. For example, a layered approach may be used such that a triangular form is obtained by QR rotation and each layer is minimized according to Eq. (1). A quantized version of the previously minimized streams may be re-substituted in the above equations in order to solve it for the subsequent stream. In such an embodiment, the MIMO processing (detection) is absorbed into the least squares minimization of the above equations.

### Pre-PA Modeling

In addition to modeling the PA of the transmitter, the NLS circuitry 216 may also model linear and non-linear response of pre-PA circuitry which operates on x(t) (121 in FIG. 1). In particular, two dominant components may be present: The DNF circuitry 124 (e.g. exhibiting a protective clip response, ƒ_{PC}(x); and the linear response (h_{prePA}) of interpolation filters and analog filtering before PA.

The protective clip of the DNF circuitry 124 may have the form shown in equation (12).

$${f}_{PC} ( x ) = \{ \begin{matrix}x , & \vert x \vert < pclip \\ x / \vert x \vert \cdot pclip , & \vert x \vert \geq pclip\end{matrix} \qquad ( 12 )$$

where pclip is the threshold at which the DNF circuitry 124 clips the transmission signal in order to remain in well behaved PA input range (e.g., not exceed a threshold amount of compression).

The combined response, for which the gradient (substantially using the derivation chain rule) is to be calculated may therefore be given by equation (13).

ƒ^{j}_{NL}(h_{prePA}*ƒ_{PC}(x)) (13)

where ƒ^{j}_{NL} models the non-linear response of the j^{th} antenna PA.

Thus, the sampling rate and bandwidth of the DAC and anti-aliasing filters 126, should be wide enough to accommodate the bandwidth of ƒ_{PC}(x) (which is relatively wide due to clips).

In an example implementation where h_{prePA} is not too sharp (e.g., rolls off less than some threshold amount per decade) within this bandwidth, the transmitter can digitally compensate for h_{prePA} (e.g., by amplifying frequencies that are attenuated by h_{prePA}). In an example implementation where h_{prePA} must be made sharp (e.g. to prevent transmitting aliases), the transmitter can compensate for h_{prePA} to transform it to a linear response—h_{prePA0}—that is known to the receiver and would be modeled by NLS circuitry 216. In another example, if the transmitter uses digital predistortion, the combined response ƒ_{NL}(h_{prePA}*ƒ_{PC}(x)) may be transformed to a soft limiter ƒ_{PC}(x) (e.g., by digital predistortion circuitry residing between 124 and 126 in FIG. 1). In another example implementation the receiver may use the training sequence used to estimate ƒ_{NL} and channel, also to estimate h_{prePA0}. In this case the receiver models h_{prePA0} as part of ƒ_{NL} in the minimization of the NLS cost function (e.g. equation (5)).

### Soft Bounds Gradient

For a soft bounds approach, a penalty term (6) is added to the cost, and the NLS circuitry 216 computes the corresponding gradient as shown in (14).

$${Bound}_{GD} = 2 ( re ( x ) > {X}_{ma x} ) ( re ( x ) - {X}_{ma x} ) + 2 ( re ( x ) < - {X}_{ma x} ) ( re ( x ) + {X}_{ma x} ) + 2 ( im ( x ) > {X}_{ma x} ) ( im ( x ) - {X}_{ma x} ) + 2 ( im ( x ) < - {X}_{ma x} ) ( im ( x ) + {X}_{ma x} ) \qquad ( 14 )$$

where
Xₘₐₓ is maximum constellation value (e.g. 31 for 1024 QAM)
(a>b) is 1 if a is greater than b is true and zero otherwise

### Gradient Descent Algorithm

Denoting the gradient computed in (10) as Gₖ

The Gradient decent algorithm can then be expressed as in equation (15).

$$Δ {X}_{k}^{( i + 1 )} = Δ {X}_{k}^{( i )} \cdot {μ}_{k} \cdot ( {G}_{k} + η \cdot {Bound}_{GD} - \frac{2 Δ {X}_{k}^{( i )}}{{σ}_{k}^{2}} ) \qquad ( 15 )$$

where μₖ is a step size, that is 0 for good bins, and a non-zero fixed value for bad bins.

Constellation soft bounds are handled by η·Bound_{GD} and are based on (13), where η is a scaling factor. The last term of equation (15), corresponding to last term in (5), may be used as a ‘soft-metric’. It is noted that the nonlinear model, though extensive, is just an example. Other, even more elaborate models may be used and a similar derivation may be applied.

In an example implementation, the transmitter and receiver of FIGS. 1 and 3 may use Bit-Interleaved-Coded-Modulation (BICM) (e.g. LDPC). In such an implementation, output 225 of the SISO FEC decoder 224 comprises per-bit Log-Likelihood-Ratios (LLRs). In an example implementation, Euclidean coding (e.g. trellis coded modulation (TCM) or modulation as described in U.S. Pat. No. 8,582,637, which is hereby incorporated herein by reference) may be used to provide likelihood in the Euclidean domain.

### Micro FEC Iterations

In an example implementation, the FEC decoder 224 may be an iterative decoder. In an example implementation, the iterative decoder may be run a sufficient number of iterations until it fully converges. However, since the FEC decoder 224 needs to be run for multiple outer iterations, the overall decoder complexity is significant. In an example implementation, in order to reduce the decoding complexity, the iterative FEC decoder 224 is not run until it converges, but rather is stopped substantially prematurely. Despite stopping prematurely, state (accumulated extrinsic information) of the iterative FEC decoder 224 may be maintained and not be reset every outer iteration. With a message passing decoder, this maintenance of state information may be accomplished by continuing the message passing across outer iterations (i.e., messages generated but not processed at outer iteration q, since decoding was stopped, are processed at outer iteration q+1.) In general, this corresponds to adding the NLS circuitry 216 as additional check nodes in a Tanner graph which combines both FEC and nonlinearity constraints.

To illustrate, an example implementation in which the FEC decoder 224 is an LDPC decoder will now be described using the following notation:
i,j—the variable node and check node indices correspondingly
L(i)—The LLR of code bit i obtained from demapper 220
L(rⱼᵢ)—Message from check node j to variable node i
L(qᵢⱼ)—Message from variable node i to check node j
Cᵢ—Set of check nodes connected to variable node i
Vⱼ—Set of variable nodes connected to check node j

At each outer iteration, the LDPC decoder 224 is fed with output L(i) from demapper 220. Then, the LDPC decoder 224 applies (16) to L(i) and the L(rⱼᵢ) messages stored from the previous outer iteration (denoted L(r_{j′i})), where for the first outer iteration L(r_{j′i})=0) to generate variable node to check node messages. The L(r_{j′i}) messages were generated using (17) to compute the decoded bits output LLRs by the LDPC in the previous outer iteration and, as said, are then processed using (16) to generate messages to check nodes in current (successive) outer iteration. In the current outer iteration, the latest NLS updated L(i), and not the old L(i) that was used for the previous outer iteration, is used in (16).

The LDPC algorithm runs several inner iterations of the form shown in equations

(16) and (17).
Variable node to check node messages:

∀i,j:L(qᵢⱼ)=L(i)+Σ_{j′εC}_{ᵢ}_{-{j}}L(r_{j′i}) (16)
Check node to variable node messages:

$$∀ j , i \text{:} L ( {r}_{ji} ) = 2 atanh ( {Π}_{{i}^{′} ∈ {V}_{j} - \{ i \}} tanh ( \frac{1}{2} L ( {q}_{{i}^{′} j} ) ) ) \qquad ( 17 )$$

After completing the LDPC iterations, the final check node to variable node messages L(rⱼᵢ) are stored for the next outer iteration, and the LLRs output by FEC decoder 224 are computed using equation (18).

$${L}_{out} ( i ) = L ( i ) + {\sum }_{{j}^{′} ∈ {C}_{i}} L ( {r}_{{j}^{′} i} ) \qquad ( 18 )$$

In the example just discussed, Tanner graph iterative decoding was used in a way that alternates between NLS check node iterations and FEC check node iterations, repeating for some number of outer iterations which may be predetermined and/or dynamically determined. In other implementations, the FEC+NLS Tanner graph based decoder may be iterated in different ways. For example, the NLS and FEC check node may be iterated in parallel, or subsets of NLS and FEC check nodes may be iterated sequentially or in parallel. A similar approach is applicable for other iterative decoders.

### Channel Response and Distortion Estimation

As used here, the “channel response” is the response of the communication medium (e.g., air, copper cable, fiber, etc.) between the output (e.g., antenna for wireless) of the transmitter and the input (e.g., antenna for wireless) of the receiver, and does not include the power amplifier or receiver circuitry.

Learning Channel response and the nonlinear PA models ƒ^{j}_{NL}, jε1 . . . N_{Tx}, for N_{Tx} transmit antennas may be accomplished is several ways. In an example implementation, the link between a transmitter and a receiver may be established with low-baud-rate packets using low-order modulations (and/or low-amplitude symbols of a higher-order modulation) which are less vulnerable to nonlinear distortion. The receiver may then recover the payload of such packets (using FEC decoding, which may be reliable because of the relatively low amounts of nonlinear distortion in these packets) to recover the transmitted symbols, and then determine the channel response and nonlinear distortion through a comparison of the received symbols with the transmitted symbols. In an example implementation, when the transmitter knows its nonlinear response, a representation of ƒ^{j}_{NL} (or just a parametric model of ƒ^{j}_{NL} to simplify receiver learning) may be directly transmitted in a payload of such packets. Thereafter, the link may upgrade to higher modulation orders, and/or higher-amplitude symbols, which may be demodulated by using the learned nonlinear model. In another example implementation, the transmitter-receiver pair may use probe signals, known to the receiver a priori, to learn the nonlinear model, where the probe signals may be as specified by an applicable standard. As another example, additional training signals, to be used by the intended receiver for channel estimation and learning of the nonlinear characteristic of the transmitter, may be appended to preambles defined in existing standards.

In an example implementation, the channel response (H) may be estimated using preamble(s) or beacon(s) which have low peak-to-average-power ratio (PAPR) such that it suffers only a negligible amount of nonlinear distortion. In an example implementation, the preambles or beacons may intentionally have high PAPR (thus experiencing relatively severe nonlinear distortion), but may be generated/selected to have characteristics (e.g., occupying at least a determined number and/or range of frequencies, occupying at least a determined number of signal levels, and/or providing at least a determined amount of repetition of frequencies and/or signal levels) that allow the same preamble or beacon to be used for both nonlinearity estimation and channel response estimation. In an example implementation, the channel response (H) may be estimated as part of the iterative process performed in the NLS circuit 216, as discussed below.

In an example implementation, in order to estimate both distortion and channel response from the same preamble, the receiver may operate to separate distortion effects and channel effects. To enable this separation, special sequences having the following properties may be transmitted by the transmitter: The sequence is composed of a set of N values that, in the time domain, is denoted as p_{[0]}, p_{[1]} . . . P_{[N-1]}, this set of values is rich enough (e.g., a sufficient number and/or diversity of power levels are present in the sequence) to capture both nonlinearity and channel response (e.g., as few as two levels may suffice for estimating the channel response but more levels may be better for estimating the nonlinearity). The preamble is then composed of a permutation of M such sets of these N values. Therefore circuitry for estimating the distortion and channel (e.g., the NLS circuitry 216) needs to estimate a finite number (N) of distorted transmitted values of the form ƒ_{NL}(p_{[k]}) for k=0 . . . N−1, and the channel response h_{[0]}, h_{[1]} . . . h_{[T-1]}, where [symbol] is the length of the channel response. This results in N+ [symbol] unknowns with N·M equations, so M>=1+ [symbol] /N is needed for a unique solution. In addition, smoothness constraints may be placed on the estimated nonlinearity in order to reduce estimation noise and/or to reduce the required value of M. By repeating the same values (the M permutations), the number of unknowns remains constant even when preamble length increases, thus enabling a unique solution. In an example implementation, the value of N is selected based on the desired granularity with which it is desired to estimate ƒ_{NL}. This granularity and the set of values selected (p_{[0]}, p_{[1]} . . . p_{[N-1]}) is not necessarily uniformly spaced, as, for example, lower sampling granularity may be used for lower voltage levels (where ƒ_{NL} has low distortion) and higher granularity at higher voltage levels (that are highly distorted). Once the set of preamble values p_{[0]}, p_{[1]} . . . p_{[N-1]} have been determined, a plurality of pseudo random permutations of these values are selected for transmission to support distortion and channel estimation. In an example implementation, the permutations are selected such that the resulting preamble segments are substantially white in frequency.

In an example implementation, the channel response may be estimated using a time domain synchronous (TDS)-OFDM scheme where, instead of using pilots for channel estimation, the guard period is utilized for transmission of a training sequence (i.e. data that is known to the intended receiver a priori). This scheme is appropriate for the case where the received signal is distorted since the training sequence can be selected to have a desired PAPR (and thus desired amount of nonlinear distortion). By selecting the training sequence, which operates in the time domain, to have a low PAPR (and thus distortion), it can be used for accurate channel estimation. In an example implementation using the TDS-OFDM approach, the same training sequence may be used for nonlinearity estimation on top of channel response estimation. In an example implementation, the TDS-OFDM scheme may be used for nonlinearity estimation (i.e., to determine f_{NL}) but not channel estimation.

In an example implementation using TDS-OFDM, where the data symbol is preceded by a training sequence, the receiver may use a permuted sequence approach similar to that described above. In this case, the same basic set of values p_{[0]}, p_{[1]} . . . P_{[N-1]} where N> [symbol] may be used every TDS-OFDM training sequence, but with each symbol using a different permutation of the same sequence of values. In such an implementation, the receiver may use multiple training sequences (from multiple symbols) to estimate or improve estimation of both the channel response and the nonlinearity. This permuted training sequence is also useful to reduce correlation between the desired signal training sequence, and any interfering sequence of co-channel signals (e.g., interference between different users belonging to different cells in a cellular system).

In an example implementation, a TDS-OFDM scheme may be used for deriving the off-diagonal elements of H for phase noise compensation. In an example implementation, these elements are determined by calculating one or more derivatives (e.g., the 1^{st} and/or 2^{nd} derivative(s)) of H. In an example implementation, the NLS circuitry 216 may calculate the calculate the derivative(s) using: (1) the training sequence of a current symbol, (2) training sequence of a next symbol, and (3) tentative decisions of X for the current symbol. Thus, the channel response can be estimated along 3 time instances which enables calculating 1^{st} and 2^{nd} derivative.

In an example implementation the channel may be estimated using \hat{X} at output of circuit 232, or \hat{X}+ΔX at output of NLS circuitry 216. This can be done in the following way: The signal expected to be present at the transmission antenna array (at PA output) can be expressed using the block diagonal formulation of (19):

z=DFT(ƒ_{NL}(IDFT(V·\hat{X}))) (19)
where:
z is a N_{Tx}·N_{FFT}×1 vector;
z(k·N_{Tx}+[0:N_{Tx}−1]) is the output of the PA output for subcarrier k and transmit antennas 1:N_{Tx};
\hat{X} vector is estimated spatial streams sig stacked over all subcarrier (discussed above);
V is the block diagonal precoding matrix discussed above.

Using z, the signal at the transmission antenna array, and y, the signal at reception antenna array, both measured over several symbols, the receiver can estimate the channel response Hₖ for every bin k, since:

y(k·N_{Rx}+[0:N_{Rx}−1])=Hₖ·z(k·N_{Tx}+[0:N_{Tx}−1]) (20)

where y is a N_{RXBINS}×1 vector, is the Rx antenna's signal stacked over all subcarriers; and Hₖ is the channel response for bin k.

In an example implementation, the channel response Hₖ is additionally smoothed according to channel coherence bandwidth, power delay profile, of a combination of the two. Thus, even if \hat{X} is with errors, the smoothing enables accurate channel estimation. Thus, per each iteration when errors decrease, the NLS circuitry 216 can derive an improved channel estimation. For the 1^{st} iteration on a particular OFDM symbol, in slow-varying channels, the NLS circuitry 216 may use the channel estimation of a previous symbol (the immediately previous symbol or an even earlier symbol). For the 1^{st} iteration on a particular OFDM symbol, in fast-varying channels, the NLS circuitry 216 may use a TDS-OFDM or similar scheme.

In an example implementation, e.g. where transmit power control continuously changes the input backoff, the transmitter may inform the receiver of its current input backoff. In an example implementation this can be transmitted using the packet header and, assuming the packet header uses lower constellations, for example, then it can be demodulated despite the compression. This allows the receiver to use the ƒ_{NL} estimation computed for a previous packet but compensated for input backoff changes. The previous ƒ_{NL} estimation may be used either instead of ƒ_{NL} estimation from training sequence or in addition to it (to reduce estimation noise). When input backoff changes the transmitter may also vary the protective clip saturation level to correspond to an approximately fixed level below analog Psat. In an example implementation, the protective clip saturation level is a function of input backoff. The receiver can then use input backoff transmitted as part of the header to set its expected protective clip level to be exactly equal to that of the transmitter.

### Efficient Use of Cyclic Prefix

As is well known, the cyclic prefix in OFDM is used to avoid ISI and to simplify equalization to per bin multiplication, by turning linear convolution into cyclical convolution. However OFD WAM Receiver does equalization implicitly via the cost function minimization, and handles distortion between demodulated bins by use of iterative convergence. Therefore avoiding ISI and simplified equalization are not needed thus OFD WAM Receiver can work without a cyclic prefix (CP) or alternately use the energy of the CP. With No CP OFD WAM receiver we can model the linear convolution including the previous symbol ISI using the following cost function:

$$\frac{1}{{σ}_{v}^{2}} {\sum }_{i = 1}^{{N}_{Rx}} {\sum }_{n = 0}^{{N}_{FFT} - 1} {\vert \begin{matrix}\begin{matrix}{y}_{i} ( n ) - {\sum }_{j = 1}^{{N}_{Tx}} {\hat{h}}_{i , j}^{ISI} ( n ) * \\ ( {{f}_{NL}^{j} [ IDFT ( {\sum }_{s = 1}^{{N}_{SS}} {V}_{j , s , :} \cdot ( {\hat{X}}_{s , :}^{t - 1} ) ) ]}_{n} ) -\end{matrix} \\ \begin{matrix}{\sum }_{j = 1}^{{N}_{Tx}} {\hat{h}}_{i , j} ( n ) * \\ ( {{f}_{NL}^{j} [ IDFT ( \begin{matrix}{\sum }_{s = 1}^{{N}_{SS}} {V}_{j , s , :} \cdot \\ ( {\hat{X}}_{s , :}^{t} + Δ {X}_{s , :}^{t} )\end{matrix} ) ]}_{n} )\end{matrix}\end{matrix} \vert}^{2} + {\sum }_{s = 1}^{{N}_{SS}} {\sum }_{k = 0}^{{N}_{FFT} - 1} \frac{{\vert Δ {X}_{s , k}^{t} \vert}^{2}}{{( {σ}_{s , k}^{t} )}^{2}} + \frac{{\vert Δ {X}_{s , k}^{t - 1} \vert}^{2}}{{( {σ}_{s , k}^{t - 1} )}^{2}} , \qquad ( 21 )$$

where:
\hat{X}^{t}, \hat{X}^{t-1} are the current and previous estimated symbols;
ΔX^{t}, ΔX^{t-1} are the current symbol and previous symbol corrections
σ_{s,k}^{t} is the reliability measure for subcarrier ΔX_{s,k}^{t};
yᵢ(:), is the observed signal in time domain for receive antenna i;
σᵥ²—is the noise power which here is assumed to be white;
ĥ_{i,j}(n) is channel estimation in time from antenna i to j;
ĥ^{ISI}_{i,j}(n) is previous symbol ISI channel estimation in time from antenna i to j;
V_{:,:,k} for 0≦k≦N_{FFT}−1 is the N_{Tx}×N_{SS} precoder matrix for subcarrier k;
ƒ_{NL}^{j} for 1≦j≦N_{TX}, is the nonlinear response of the j'th transmit chain;
The IDFT/DFT represents IDFT/DFT operations operating on the input samples of size N_{FFT}.

In this case summation occurs not only over N_{FFT} samples, but also over the CP part. Thus, if the system uses a CP the energy of the CP is not wasted. The ISI from the previous symbol is mitigated by use of the estimate for the previous symbol convolved with the ISI response (ĥ^{ISI}_{i,j}(n)), where, through the use of pipelining, as discussed below, the previous symbol estimate (\hat{X}_{S,:}^{t-1}) NLS circuitry 216 processes the previous symbol independent of the current symbol, and the previous symbol has undergone more outer iterations than the current symbol. The receiver may also use non-cyclic convolution with the channel response (ĥ_{i,j}(n)).

In addition, it is possible to concurrently optimize two or more symbols thereby further increasing performance. I.e. summing cost function of several symbols. For example, the corrections ΔX_{S,:}^{t}, ΔX_{S,:}^{t-1}, ΔX_{S,:}^{t-2} for times t, t−1, and t−2 may be optimized concurrently.

### Pipelined Structure of Hardware

In an example implementation, the receiver of FIG. 3 may use a pipelined hardware architecture in which several receive paths operate concurrently on several code words. In such an implementation, a first path may handle outer iteration J (a positive integer) on code word M while, a second path (if present) may operate on outer iteration J−1 on code word M+1, a third path (if present) may concurrently operate on outer iteration J−2 on code word M+2, and so on for as many paths as is desired. In an example implementation comprising at least two such paths, during the 1^{st} iteration (in slow varying channels), processing of OFDM symbols belonging to code word M+1 may use channel estimation based on symbols belonging to the second iteration of code word M. In an example implementation, the derivative of the channel for symbols belonging to code word M, iteration J can be derived from the channel estimation from symbols belonging to code word M−1, iteration J+1 and the channel estimation from symbols belonging to code word M+1, iteration J−1.

For the case of misalignment between code words and symbols, operating the NLS circuitry 216 code word by code word (i.e. not pipelined) may induce some performance loss because, when applying NLS circuitry 216 for code word M that shares a symbol with code word M+1, the NLS circuitry 216 has no estimation (\hat{X}ₖ) from the FEC decoder 224 for bins in the shared symbol belonging to code word M+1. In an example implementation, the pipelined implementation is used to obtain \hat{X}ₖ for the shared symbol. That is, the first path may handle outer iteration J (a positive integer) on code word M while a second path (if present) may operate on outer iteration J−1 on code word M+1. In this case, for first path outer iteration J running on last/shared symbol (of code word M), the NLS circuitry 216 may use the shared symbol bins estimations \hat{X}ₖ obtained by the FEC decoder 224 for second path outer iteration J−1 on code word M+1.

The pipelined structure can also be used in an OFDMA scenario where different packets from different users (on adjacent frequencies) are not aligned. In OFDMA, non-linear distortion leaks from one user to the adjacent users in frequency. The NLS circuitry 216 can start processing a user packet as soon as a code word becomes available without using “goods” which are related to code words that haven't been processed yet. However, whenever an adjacent (in frequency or time) code word has been processed, the NLS circuitry 216 may use the most recent soft information obtained for it by the decoder 224 (LLRs, estimation \hat{X}ₖ, and/or other information).

### Using Off Diagonal Elements in H to Handle Phase Noise and Fast Varying Channels.

The derivation for the SISO case (single spatial path) applies to N_{Rx}·N_{Tx} physicals channel from every transmit antenna to every receiver antenna, and thus can be used in the MIMO case as well. The channel is assumed to be composed of several reflections, each reflection delays the transmitted signal and multiplies it by a complex factor. The formulation for such a channel between single TX and single RX antenna is shown in equation (22).

$$h ( t ) = {\sum }_{i} {h}_{i} ( t ) \cdot δ ( t - {τ}_{i} ) \qquad ( 22 )$$

where, in slow varying channels (e.g., where estimation using a one-symbol delay is provides sufficient SNR), and when phase noise is weak enough (e.g., below a determined threshold), it is assumed that hᵢ(t) is constant within the duration of an OFDM symbol. However, in the presence of phase noise and/or when channel varies fast this assumption no longer holds. In this case, a Taylor expansion may be used around the middle of the OFDM symbol, which results in the formulation of equation (23).

$${h}_{i} ( t ) = {h}_{i} ( {T}_{SYM} / 2 ) + {\sum }_{p = 1}^{P} \frac{{h}_{i}^{( p )}}{p !} \cdot {( t - \frac{{T}_{SYM}}{2} )}^{p} \qquad ( 23 )$$

where hᵢ^{(p)} is the p^{th} derivative of hᵢ(t) at the middle of the OFDM symbol (i.e. at time instant T_{sym}/2).

Using (23), and under the assumption that the cyclic prefix is longer than the maximal path delay, τ, it can be shown that received signal in frequency domain is:

$${Y}_{k} = {H}_{k} \cdot {X}_{k} + {\sum }_{p = 1}^{P} ( {X}_{k} \cdot {H}_{k}^{( p )} ) * {L}^{( p )} \qquad ( 24 )$$

### Where:

L^{(p)} is the Fourier transform of

$$\frac{{( t - \frac{{T}_{SYM}}{2} )}^{p}}{p !} ( i . e . {L}_{k}^{( p )} = \frac{1}{p !} {\int }_{0}^{{T}_{SYM}} {( t - \frac{{T}_{SYM}}{2} )}^{p} \cdot {e}^{( j \frac{2 \cdot π \cdot k \cdot t}{{T}_{SYM}} )} \cdot d t )$$

* denotes convolution

$${H}_{k} = {\sum }_{i} {h}_{i} ( {T}_{SYM} / 2 ) \cdot {e}^{j \cdot 2 \cdot π \cdot k \cdot {τ}_{i}}$$

$${H}_{k}^{( p )} = {\sum }_{i} {h}_{i}^{( p )} \cdot {e}^{j \cdot 2 \cdot π \cdot k \cdot {τ}_{i}}$$

Equation (24) can be represented in matrix form as shown in equation (25).

Y=H·X (25)

where:

$${H}_{\underline{\_}} = diag ( [ \begin{matrix}{H}_{0} & … & {H}_{k} & … & {H}_{N - 1}\end{matrix} ] ) + {\sum }_{p = 1}^{P} {{L}_{\underline{\_}}}^{( p )} \cdot diag ( [ \begin{matrix}\begin{matrix}{H}_{0}^{( p )} & … & {H}_{k}^{( p )} & …\end{matrix} & {H}_{N - 1}^{( p )}\end{matrix} ] )$$

L^{(p)} is the convolution matrix of L^{(p)}.

Since L^{(p)} decays, which accounts for the fact that the variations cause Inter Carrier Interference (ICI) that diminishes as carriers are further apart, considering only a few off-diagonal elements is sufficient in an example implementation.

Approximation of Hₖ^{(p)} requires knowledge of Hₖ at p+1 time instances for every (TX,RX) antenna pair. In an example implementation this is done by use of pilots from the every transmit antenna that are repeated every few OFDM symbols.

Applying the previous derivation to every transmit receive antenna pair we get the following output for RX antenna i.

$${\underline{Y}}_{i} = {\sum }_{j = 1}^{{N}_{TX}} {{H}_{\underline{\_}}}_{i , j} \cdot {\underline{X}}_{j} \qquad ( 26 )$$

### Where:

i, j are the receive and transmit antenna indices respectively;
H_{i,j} is the ICI corrupted channel from transmit antenna j to receive antenna l;
Xⱼ is the MIMO precoded signal on transmit antenna j.

Equation (5), by virtue of using the block diagonal formulation, can be applied to ICI case by setting Ĥ (Due to ICI modeling this modified Ĥ would no longer have the block diagonal form)

\hat{H}(k·N_{Rx}+i−1,k·N_{Tx}+j−1)=H_{i,j} (27)

Where i, j are the receive and transmit antenna indices respectively.

As utilized herein the terms “circuits” and “circuitry” refer to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As utilized herein, “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}. As utilized herein, the terms “e.g.,” and “for example” set off lists of one or more non-limiting examples, instances, or illustrations. As utilized herein, circuitry is “operable” to perform a function whenever the circuitry comprises the necessary hardware and code (if any is necessary) to perform the function, regardless of whether performance of the function is disabled, or not enabled, by some user-configurable setting.

The present method and/or system may be realized in hardware, software, or a combination of hardware and software. The present methods and/or systems may be realized in a centralized fashion in at least one computing system, or in a distributed fashion where different elements are spread across several interconnected computing systems. Any kind of computing system or other apparatus adapted for carrying out the methods described herein is suited. A typical combination of hardware and software may be a general-purpose computing system with a program or other code that, when being loaded and executed, controls the computing system such that it carries out the methods described herein. Another typical implementation may comprise an application specific integrated circuit or chip. Some implementations may comprise a non-transitory machine-readable (e.g., computer readable) medium (e.g., FLASH drive, optical disk, magnetic storage disk, or the like) having stored thereon one or more lines of code executable by a machine, thereby causing the machine to perform processes as described herein.

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, it is intended that the present method and/or system not be limited to the particular implementations disclosed, but that the present method and/or system will include all implementations falling within the scope of the appended claims.

What is claimed is:

1. A System comprising:
an orthogonal frequency division multiplexing (OFDM) receiver comprising a nonlinearity compensation circuit and a soft-input-soft-output (SISO) forward error correction (FEC) decoder which are operated iteratively, wherein for a particular iteration:
said nonlinearity compensation circuit is operable to generate estimates of constellation points transmitted on each of a plurality of bins of a received signal, wherein:
each of said bins corresponds to a respective one of a plurality of subcarrier and spatial stream combinations; and
said estimates are generated based on decoded soft bit decisions generated by said SISO FEC decoder during a previous iteration;
said SISO FEC decoder is operable to generate soft bit decisions generated from said estimates to generate decoded soft bit decisions for said particular iteration.

2. The system of claim 1, comprising a demapper operable to:
generate said soft bit decisions from estimates of said bins; and
output said generated soft bit decisions for decoding by said SISO FEC decoder.

3. The system of claim 1, comprising a multiple-input-multiple-output (MIMO) equalizer and decoder.

4. The system of claim 3, wherein said MIMO equalizer and decoder is operable to:
generate said soft bit decisions from estimates of said bins; and
output said generated soft bit decisions for decoding by said SISO FEC decoder.

5. The system of claim 3, wherein said MIMO equalizer and decoder is operable to:
receive said estimates from said nonlinearity compensation circuit; and
for each of said plurality of subcarrier and spatial stream combinations, generate a corresponding one of a plurality of lists of candidates to be used for calculation of said soft bit decisions.

6. The system of claim 5, wherein each one of said plurality of lists of candidates is generated independently of each other one of said plurality of lists of candidates.

7. The system of claim 5, wherein said MIMO equalizer and decoder is operable to perform linear decoding.

8. The system of claim 5, wherein said MIMO equalizer and decoder is operable generate said plurality of lists of candidates based on a cost function that is based on a model of nonlinearity of a transmitter from which a signal being decoded was received.

9. The system of claim 7, wherein said MIMO equalizer and decoder is operable to generate said plurality of lists of candidates using a gradient method to solve for one subcarrier at a time while the other subcarriers are fixed to said estimates generated by said nonlinearity compensation circuitry.

10. The system of claim 1, wherein said nonlinearity compensation circuit is operable to generate said estimates based on a cost function that is based on a model of nonlinearity of a transmitter from which a signal being decoded was received.

11. The system of claim 10, wherein:
said cost function does not completely account for correlation between noise components over different spatial streams of a particular subcarrier; and
said OFDM receiver comprises a MIMO decoder operable to extract said correlation between noise components over said different spatial streams of said particular subcarrier.

12. The system of claim 1, wherein said generation of said estimates is based on a measure of distance that is either: between a function of said received signal and a synthesized version of said received signal, or between said estimates and said decoded soft bit decisions.

13. The system of claim 1, wherein:
said iterative operation of said nonlinearity compensation circuit and said SISO FEC decoder comprises processing comprises a plurality of outer iterations and a plurality of inner iterations;
said particular iteration is one of said plurality of outer iterations; and
said previous iteration is another one of said plurality of outer iterations.

14. The system of claim 13, wherein for each of said inner iterations for said particular iteration, said SISO FEC decoder is operable to generate variable-node-to-check-node messages based on said estimates.

15. The system of claim 13, wherein:
for a first one of said inner iterations for said particular iteration, said FEC decoder is operable to generates variable-node-to-check-node messages based on check-node-to-variable-node messages generated during a last one of said inner iterations for said previous iterations.

16. The system of claim 15, comprising circuitry operable to: for said previous iterations, halt said inner iterations before said FEC decoder converges.

17. The system of claim 13, comprising circuitry operable to:
categorize said decoded soft bit decisions from said previous iteration; and
adjust said decoded soft bit decisions based on a category into which they are placed, wherein:
said adjustment results in adjusted soft bit decisions; and
said estimates for said particular iteration are generated based on said adjusted soft bit decisions.

18. The system of claim 13, comprising circuitry operable to:
for a particular one of said outer iterations, calculate an expectation using said decoded soft bit decisions, wherein said generation of said estimates is based on said expectation.

19. The system of claim 13, wherein said generation of said estimates is a refinement of estimates generated during said previous iteration.

20. The system of claim 19, wherein:
said refinement is limited by one or more constraints; and
said constraints are determined based on said decoded soft bit decisions.
